(19) United States
(12) Patent Application Publication
(10) Pub. No.: US 2025/0140618 A1
(43) Pub. Date: May 1, 2025

(54) PIXEL ARRAY SUBSTRATE AND FABRICATION METHOD OF DISPLAY DEVICE

(71) Applicant: AUO Corporation, Hsinchu City (TW)

(72) Inventors: Shu-Yen Chen, Hsinchu City (TW); Teng-Fu Tung, Hsinchu City (TW)

(73) Assignee: AUO Corporation, Hsinchu City (TW)

(21) Appl. No.: 18/822,269

(22) Filed: Sep. 1, 2024

(30) Foreign Application Priority Data
Oct. 27, 2023 (TW) 112141197

(51) Int. Cl. H01L 21/66; H01L 27/12

(52) U.S. Cl. CPC H01L 22/14; H10D 86/021; H10D 86/443; H10D 86/60

(57) ABSTRACT

Disclosed is a pixel array substrate including a first conductive pattern, a first dielectric layer, and a second conductive pattern. The first conductive pattern includes scan lines and first test lines. The second conductive pattern includes gate signal lines, data lines, second test lines, a first gate test line, and a second gate test line. The data lines are respectively electrically connected to the second test lines. The scan lines are respectively electrically connected to the gate signal lines, and the gate signal lines are respectively electrically connected to the first test lines. First portion of the gate signal lines are electrically connected to the first gate test lines, while second portion of the gate signal lines are electrically connected to the second gate test line. The first portion of the gate signal lines and the second portion of the gate signal lines are alternately arranged.

### CROSS-REFERENCE TO RELATED APPLICATION

This application claims the priority benefit of Taiwan application serial no. 112141197, filed on Oct. 27, 2023. The entirety of the above-mentioned patent application is hereby incorporated by reference herein and made a part of this specification.

### BACKGROUND

### Technical Field

The present disclosure relates to a pixel array substrate and a fabrication method of a display device.

### Description of Related Art

Nowadays, people want to acquire information at any time anywhere, and therefore many manufacturers continuously develop new electronic display devices to meet people's needs. The electronic paper technology adopted in electrophoretic display (EPD) panels has attracted a lot of attention. The displayed image using such technology has an effect similar to printing ink on paper, allowing users to watch for a long time without feeling eye fatigue. Therefore, the electronic paper technology has been commonly applied in many e-book reading devices. In addition, electrophoretic display (EPD) panels are also characterized in extremely low energy consumption, which makes EPD panels to be particularly suitable for use in many portable electronic devices. Therefore, EPD technology not only performs well in e-book readers, but also in various applications such as smart watches, price tags, and advertising billboards.

### SUMMARY

At least one embodiment of the present disclosure provides a pixel array substrate and a fabrication method of a display device. Open/short tests may be used to test defects in conductive patterns during the fabrication process to ensure production yield and quality.

At least one embodiment of the present disclosure provides a fabrication method of a display device, including the following steps. A first conductive pattern is formed on the substrate, wherein the first conductive pattern includes a plurality of scan lines and a plurality of first test lines, the scan lines extend along a first direction. A first open/short test is performed on the first conductive pattern. A first dielectric layer is formed on the substrate and the first conductive pattern. A second conductive pattern is formed on the first dielectric layer, wherein the second conductive pattern includes a plurality of gate signal lines, a plurality of data lines, a plurality of second test lines, a first gate test line and a second gate test line. The data lines and the gate signal lines extend along a second direction that is not parallel to the first direction. The data lines are electrically connected to the second test lines respectively, the scan lines are electrically connected to the gate signal lines respectively, and the gate signal lines are electrically connected to the first test lines respectively. The first portion of the gate signal lines are electrically connected to the first gate test line, the second portion of the gate signal lines are electrically connected to the second gate test line, and first portion of the gate signal lines and the second portion of the gate signal lines are arranged alternately. A second open/short test is performed on the second conductive pattern. A display medium is provided on the substrate.

At least one embodiment of the present disclosure provides a pixel array substrate, including a substrate, a first conductive pattern, a first dielectric layer, and a second conductive pattern. The first conductive pattern is disposed on the substrate. The first conductive pattern includes a plurality of scan lines and a plurality of first test lines. The scan lines extend along a first direction. The first dielectric layer is disposed on the substrate and the first conductive pattern. The second conductive pattern is disposed on the first dielectric layer, the second conductive pattern includes a plurality of gate signal lines, a plurality of data lines, a plurality of second test lines, a first gate test line and a second gate test line. The data lines and the gate signal lines extend along a second direction that is not parallel to the first direction. The data lines are electrically connected to the second test lines respectively, the scan lines are electrically connected to the gate signal lines respectively, and the gate signal lines are electrically connected to the first test lines respectively. The first portion of the gate signal lines are electrically connected to the first gate test line, the second portion of the gate signal lines are electrically connected to the second gate test line, and first portion of the gate signal lines and the second portion of the gate signal lines are arranged alternately.

### BRIEF DESCRIPTION OF THE DRAWINGS

FIG. 1A to FIG. 1C are schematic top views of a fabrication method of a pixel array substrate according to an embodiment of the present disclosure.

FIG. 2A is a partial top view of a pixel array substrate according to an embodiment of the present disclosure.

FIG. 2B is a schematic cross-sectional view taken along line A-A′ of FIG. 2A.

FIG. 3A is a partial top view of a pixel array substrate according to an embodiment of the present disclosure.

FIG. 3B is a schematic cross-sectional view taken along line A-A′ of FIG. 3A.

FIG. 3C is a schematic cross-sectional view taken along line B-B′ of FIG. 3A.

FIG. 4A to FIG. 4E are schematic top views of a fabrication method of a display device according to an embodiment of the present disclosure.

FIG. 5 is a schematic cross-sectional view of a display device according to an embodiment of the present disclosure.

FIG. 6 is a three-dimensional schematic view of an open/short test according to an embodiment of the present disclosure.

### DESCRIPTION OF THE EMBODIMENTS

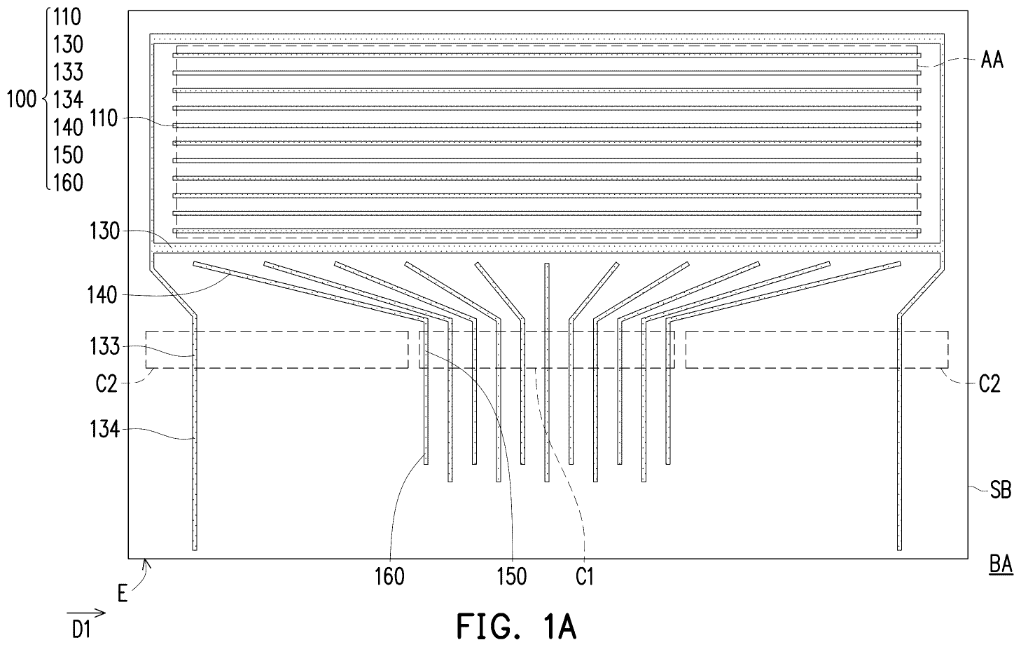

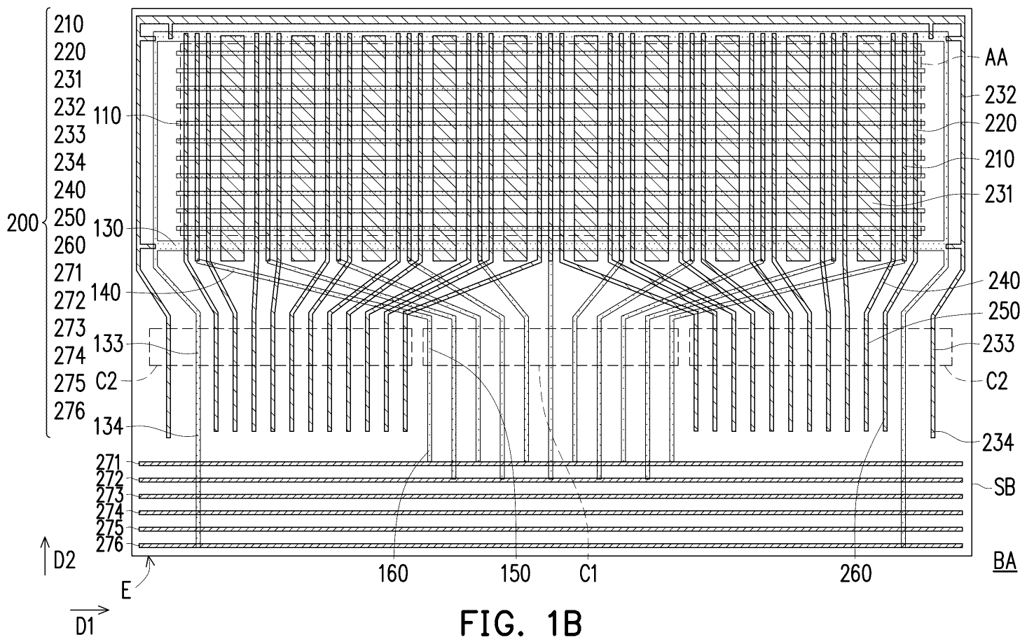

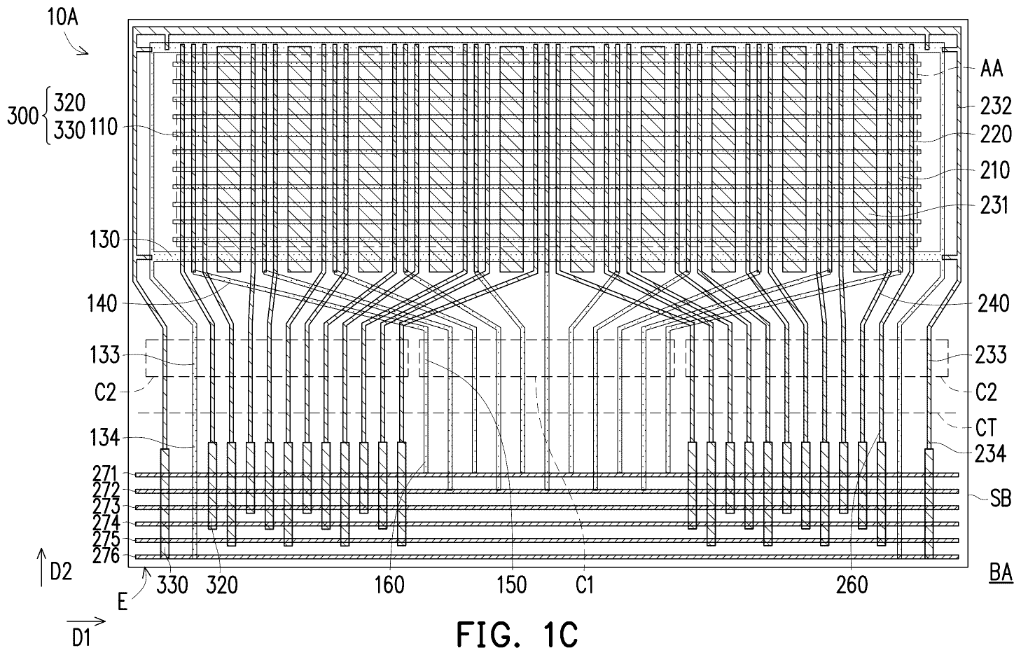

FIG. 1A to FIG. 1C are schematic top views of a fabrication method of a pixel array substrate 10A according to an embodiment of the present disclosure. For clarity, the dielectric layer, the planarization layer and the semiconductor layer of the pixel array substrate are omitted from FIG. 1A to FIG. 1C.

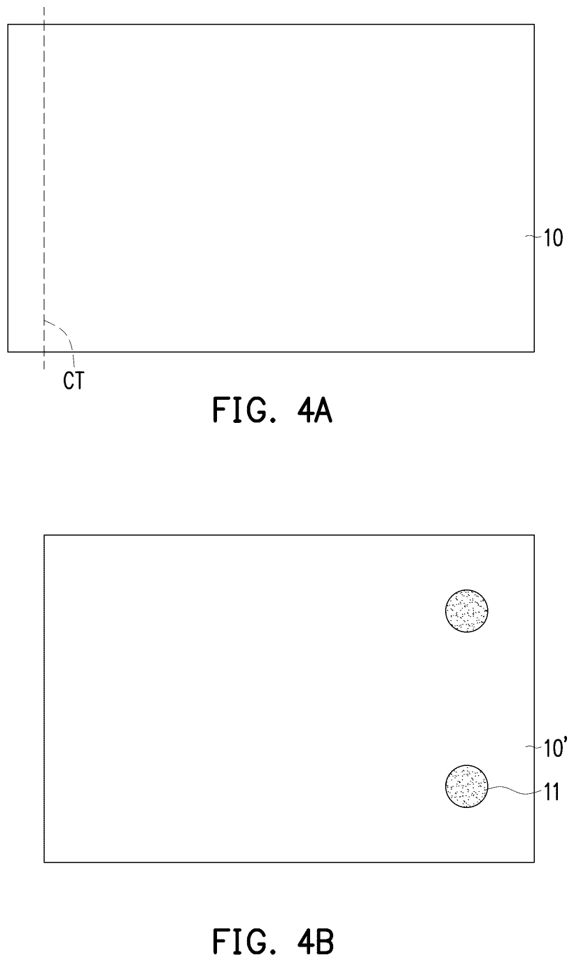

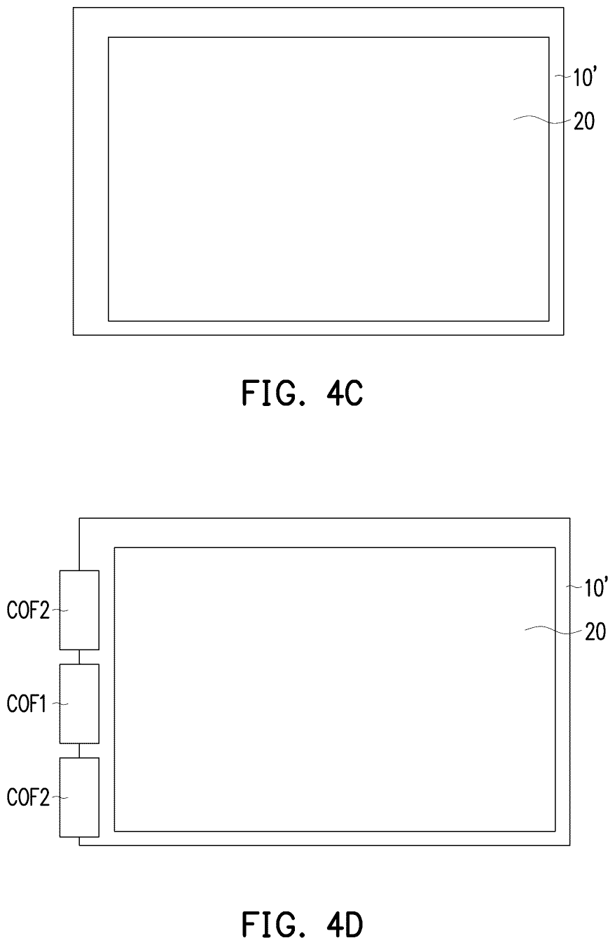

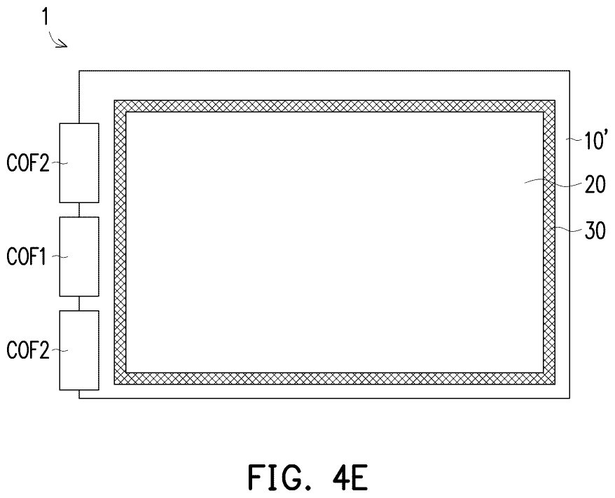

Referring to FIG. 1A, the substrate SB has an active area AA and a peripheral area BA located on at least one side of the active area AA. In some embodiments, the peripheral area BA includes a first bonding area C1 and a second bonding area C2. In some embodiments, the circuit structure (such as a thin film flip-chip packaging structure) to be subsequently disposed on the substrate SB will be disposed above the first bonding area C1 and the second bonding area C2 (please refer to FIG. 4D).

The substrate SB is, for example, a rigid substrate, and the material thereof may be glass, quartz, organic polymers or opaque/reflective materials (such as conductive materials, metals, wafers, ceramics or other applicable materials) or other applicable materials. However, the present disclosure is not limited thereto. In other embodiments, the substrate SB may also be a flexible substrate or a stretchable substrate. For example, materials for flexible substrates and stretchable substrates include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU) or other suitable materials.

The first conductive pattern 100 is formed on the substrate SB. The first conductive pattern 100 includes a scan line 110 and a first test line 160. In some embodiments, the first conductive pattern 100 further includes a first common electrode connection line 130, a first common electrode pad 133, a first common signal test line 134, a first fan-out line 140 and a gate signal pad 150. In some embodiments, the first conductive pattern 100 has a single-layer or multi-layer structure, and the material thereof includes chromium, gold, silver, copper, tin, lead, hafnium, tungsten, molybdenum, neodymium, titanium, tantalum, aluminum, zinc, nickel and other metals, alloys of the above metals, conductive oxides, conductive nitrides or combinations of the above or other conductive materials.

The scan line 110 is disposed on the active area AA and extends along the first direction D1. The first common electrode connection line 130, the first common electrode pad 133, the first common signal test line 134, the first fan-out line 140, the gate signal pad 150 and the first test line 160 are disposed on the peripheral area BA. In some embodiments, the distance between adjacent scan lines 110 is 50 microns to 550 microns.

In some embodiments, the first common electrode connection line 130, the first common electrode pad 133 and the first common signal test line 134 are electrically connected to each other, wherein the first common electrode pad 133 is disposed on the second bonding area C2, and the first common signal test line 134 is located between the second bonding area C2 and the edge E of the substrate SB. In this embodiment, the first common electrode connection line 130 includes an annular structure and surrounds the active area AA and the scan line 110. In this embodiment, the first common electrode connection line 130 may also be referred to as an inner common signal ring. In this embodiment, the entire inner common signal ring belongs to the first conductive pattern 100, but the disclosure is not limited thereto. In other embodiments, a portion of the inner common signal ring belongs to the first conductive pattern 100, and another portion of the inner common signal ring belongs to other conductive patterns.

The gate signal pad 150 is disposed on the first bonding area C1. Each gate signal pad 150 is electrically connected to a corresponding first fan-out line 140 and a corresponding first test line 160. The first fan-out line 140 is disposed between the first bonding area C1 and the active area AA, and the first test line 160 is disposed between the first bonding area C1 and the edge E of the substrate SB.

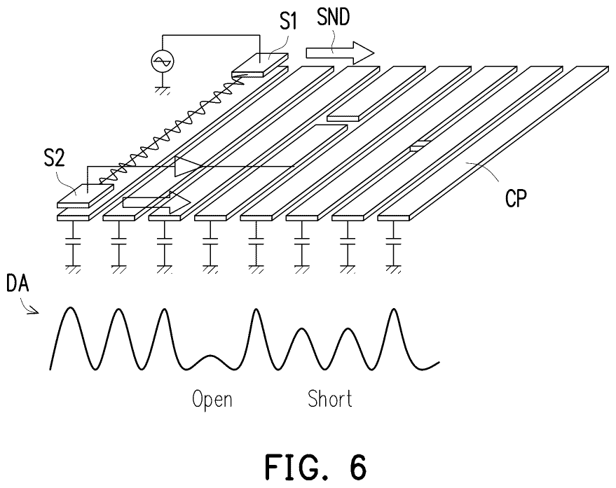

After forming the first conductive pattern 100, a first open/short test (TOS) is performed on the first conductive pattern 100. For example, the first open/short test is performed on the scan line 110. In some embodiments, the first open/short test is a non-contact detection that is performed using capacitance. The method of performing the first open/short test will be discussed subsequently in FIG. 6 and related descriptions.

Through the first open/short test, it may be immediately determined whether the first conductive pattern 100 is defective, and the defects of the first conductive pattern 100 may be repaired directly after the defect is determined. Therefore, the yield of the first conductive pattern 100 may be improved.

In some embodiments, in addition to performing the first open/short test on the first conductive pattern 100, an automated optical inspection (AOI) is further performed on the first conductive pattern 100.

In some embodiments, after forming the first conductive pattern 100, a first dielectric layer (not shown) is formed on the substrate SB and the first conductive pattern 100, and then a semiconductor pattern layer (not shown) is formed on the first dielectric layer. In some embodiments, an AOI is performed on the semiconductor pattern layer to determine whether the semiconductor pattern layer is defective. In some embodiments, the first dielectric layer is a gate dielectric layer, and the semiconductor pattern layer includes a semiconductor channel layer. The first conductive pattern 100 includes a gate (not shown). The semiconductor channel layer and the gate overlap each other and are separated by the gate dielectric layer.

In some embodiments, after forming the semiconductor pattern layer, the first dielectric layer is patterned to form openings in the first dielectric layer. The openings expose the first conductive pattern 100 thereunder. In some embodiments, an AOI is performed to determine whether the opening of the first dielectric layer (i.e., the gate dielectric layer) is defective.

Referring to FIG. 1B, a second conductive pattern 200 is formed on the first dielectric layer. A portion of the second conductive pattern 200 is connected to the first conductive pattern 100 through the opening in the first dielectric layer.

The second conductive pattern 200 includes a gate signal line 210, a data line 220, a second test line 260, a first gate test line 271 and a second gate test line 272. In some embodiments, the second conductive pattern 200 further includes a common electrode line 231, a second common electrode connection line 232, a second common electrode pad 233, a second common signal test line 234, a second fan-out line 240, a data line signal pad 250, a first color test line 273, a second color test line 274, a third color test line 275 and a peripheral common signal test line 276. In some embodiments, the second conductive pattern 200 has a single-layer or multi-layer structure, and the material thereof includes chromium, gold, silver, copper, tin, lead, hafnium, tungsten, molybdenum, neodymium, titanium, tantalum, aluminum, zinc, nickel and other metals, alloys of the above metals, conductive oxides, conductive nitrides or combinations of the above or other conductive materials.

The gate signal line 210, the data line 220 and the common electrode line 231 are disposed on the active area AA and extend along the second direction D2 that is not parallel to the first direction D1. In some embodiments, two adjacent common electrode lines 231 include two data lines 220 and a gate signal line 210 sandwiched between the two data lines 220.

The data lines 220 are electrically connected to the second test lines 260 respectively. For example, the data line signal pad 250 is disposed on the second bonding area C2. Each data line signal pad 250 is electrically connected to a corresponding second fan-out line 240 and a corresponding second test line 260, and each second fan-out line 240 is electrically connected to a corresponding data line 220. The second fan-out line 240 is disposed between the second bonding area C2 and the active area AA, and the second test line 260 is disposed between the second bonding area C2 and the edge E of the substrate SB.

In some embodiments, the second conductive pattern 200 further includes a gate signal pad (not shown). The gate signal pad of the second conductive pattern 200 overlaps the gate signal pad 150 of the first conductive pattern 100.

The scan line 110 is electrically connected to the gate signal line 210 respectively, and the gate signal line 210 is electrically connected to the first test line 160 respectively. For example, each gate signal line 210 is electrically connected to a corresponding scan line 110 through an opening in the first dielectric layer, and each gate signal line 210 is electrically connected to a corresponding first fan-out line 140 through an opening in the first dielectric layer, so that the scan line 110 is electrically connected to the first test line 160 through the gate signal line 210, the first fan-out line 140 and the gate signal pad 150.

The first gate test line 271, the second gate test line 272, the first color test line 273, the second color test line 274, the third color test line 275 and the peripheral common signal test line 276 are disposed on the peripheral area BA, and disposed between the first bonding area C1 and the edge E of the substrate SB and between the second bonding area C2 and the edge E of the substrate SB.

The first portion of the gate signal lines 210 are electrically connected to the first gate test line 271, the second portion of the gate signal lines 210 are electrically connected to the second gate test line 272, and the first portion of the gate signal lines 210 and the second portion of the gate signal lines 210 are arranged alternately. For example, the first gate test line 271 and the second gate test line 272 are electrically connected to the first test line 160 through the opening in the first dielectric layer, wherein the first portion of the gate signal lines 210 are electrically connected to the first portion of the first test lines 160 and the first gate test lines 271, and the second portion of the gate signal lines 210 are electrically connected to the second portion of the first test lines 160 and the second gate test lines 272. In some embodiments, the gate signal lines 210 in odd numbers from left to right are electrically connected to the first gate test line 271, and the gate signal lines 210 in even numbers from left to right are electrically connected to the second gate test line 272.

The first color test line 273, the second color test line 274 and the third color test line 275 are separated from the second test line 260 and used for subsequent pixel circuit testing.

In some embodiments, the second common electrode connection line 232, the second common electrode pad 233 and the second common signal test line 234 are electrically connected to each other, wherein the second common electrode pad 233 is disposed on the second bonding area C2, and the second common signal test line 234 is disposed between the second bonding area C2 and the edge E of the substrate SB. In this embodiment, the second common electrode connection line 232 is disposed outside the first common electrode connection line 130 and is electrically connected to the first common electrode connection line 130. The first common electrode connection line 130 is electrically connected to the common electrode line 231. In this embodiment, the second common electrode connection line 232 may also be referred to as an outer common signal ring. In this embodiment, the entire outer common signal ring belongs to the second conductive pattern 200, but the disclosure is not limited thereto. In other embodiments, a portion of the outer common signal ring belongs to the second conductive pattern 200, and another portion of the outer common signal ring belongs to other conductive patterns.

The peripheral common signal test line 276 is electrically connected to the first common signal test line 134. For example, the peripheral common signal test line 276 is electrically connected to the first common signal test line 134 through the opening in the first dielectric layer.

After the second conductive pattern 200 is formed, a second open/short test is performed on the second conductive pattern 200. For example, the second open/short test is performed on the gate signal line 210, the data line 220 and the common electrode line 231. In some embodiments, the second open/short test is a non-contact detection that is performed using capacitance. The method of performing the second open/short test will be discussed subsequently in FIG. 6 and related descriptions.

In some embodiments, the first portion of the gate signal lines 210 are electrically connected to each other through the first gate test line 271, and the second portion of the gate signal lines 210 are electrically connected to each other through the second gate test line 272, and the common electrode lines 231 are electrically connected to each other through the first common electrode connection line 130. In contrast, the data lines 220 are not electrically connected to each other through other wires or connecting lines. Therefore, when performing the second open/short test, the test signal at the corresponding gate signal line 210 and the test signal at the corresponding common electrode line 231 will be significantly different from the test signal at the corresponding data line 220. For example, the test signal at the corresponding gate signal line 210 and the test signal at the corresponding common electrode line 231 will appear close to the valley (similar to the signal generated by the metal feature with a short circuit problem in FIG. 6), and the test signal at the corresponding data line 220 will appear close to the peak (similar to the signal generated by normal metal feature in FIG. 6).

Through such arrangement, even if the distance between the data line 220 and the gate signal line 210 and the distance between the data line 220 and the common electrode line 231 are short, it is possible to accurately determine whether the data line 220, the gate signal line 210 and the common electrode line 231 have defects by using the difference between the test signals, and to directly repair the defects of the second conductive pattern 200 after the defects are determined. Therefore, the yield of the second conductive pattern 200 may be improved.

In some embodiments, the distance between the data line 220 and the gate signal line 210 is less than 70 microns, such as 5 microns to 80 microns. In some embodiments, the distance between the data line 220 and the common electrode line 231 is less than 70 microns, such as 4 microns to 90 microns.

In some embodiments, in addition to performing the second open/short test on the second conductive pattern 200, an AOI is further performed on the second conductive pattern 200.

In some embodiments, after forming the second conductive pattern 200, a second dielectric layer (not shown) is formed on the second conductive pattern 200 and the first dielectric layer (not shown), and then a planarization layer (not shown) is formed on the second dielectric layer.

The planarization layer is patterned to form openings in the planarization layer. The openings expose the underlying second dielectric layer. In some embodiments, AOI is performed to determine whether the openings of the planarization layer are defective.

After forming the planarization layer, a third dielectric layer (not shown) is formed on the planarization layer. The third dielectric layer is patterned to form openings in the third dielectric layer. In some embodiments, where the second dielectric layer is exposed by the opening in the planarization layer, the opening in the third dielectric layer extends into the second dielectric layer thereunder and exposes the second conductive pattern 200 under the second dielectric layer. In some embodiments, an AOI is performed to determine whether the opening of the third dielectric layer is defective.

Referring to FIG. 1C, a third conductive pattern 300 is formed above the second dielectric layer. More specifically, the third conductive pattern 300 is formed on the third dielectric layer. A portion of the third conductive pattern 300 is connected to the second conductive pattern 200 through openings of the second dielectric layer and the third dielectric layer.

In some embodiments, the third conductive pattern 300 includes a plurality of pixel electrodes (not shown), a transfer electrode 320 and a common signal transfer electrode 330. In some embodiments, the third conductive pattern 300 has a single-layer or multi-layer structure, and the material thereof includes chromium, gold, silver, copper, tin, lead, hafnium, tungsten, molybdenum, neodymium, titanium, tantalum, aluminum, zinc, nickel and other metals, alloys of the above metals, conductive oxides, conductive nitrides or combinations of the above or other conductive materials.

In some embodiments, the first conductive pattern 100, the second conductive pattern 200 and the semiconductor pattern on the active area AA form an array of thin film transistors, and each pixel electrode is electrically connected to the corresponding thin film transistor.

The transfer electrode 320 is disposed on the peripheral area BA. Each transfer electrode 320 is electrically connected to a corresponding second test line 260, allowing the data line 220 to be electrically connected to the first color test line 273, the second color test line 274 and the third color test line 275, for example, allowing the first color test line 273 to be electrically connected to the first portion of the data lines 220, allowing the second color test line 274 to be electrically connected to the second portion of the data lines 220, and allowing the third color test line 275 to be electrically connected to the third portion of the data lines 220. The first portion of the data lines 220, the second portion of the data lines 220 and the third portion of the data lines 220 are arranged alternately. In some embodiments, the first portion of the data lines 220 corresponds to one of the red sub-pixel, the green sub-pixel, and the blue sub-pixel, the second portion of the data lines 220 corresponds to another one of the red sub-pixel, the green sub-pixel, and the blue sub-pixel, and the third portion of the data lines 220 corresponds to yet another one of the red sub-pixel, the green sub-pixel, and the blue sub-pixel.

The common signal transfer electrode 330 is electrically connected to the second common signal test line 234 and the peripheral common signal test line 276.

In some embodiments, the third conductive pattern 300 further includes a gate signal pad (not shown) and a data line signal pad (not shown). The gate signal pad and the data line signal pad of the third conductive pattern 300 overlap the gate signal pad 150 of the first conductive pattern 100 and the data line signal pad 250 of the second conductive pattern 200 respectively.

In some embodiments, after the third conductive pattern 300 is formed, an AOI is performed on the third conductive pattern 300 to determine whether the third conductive pattern 300 is defective.

In some embodiments, after forming the third conductive pattern 300, a conductive oxide pattern (not shown) is formed on the third conductive pattern 300. The conductive oxide pattern covers the top surface of the third conductive pattern 300, thereby reducing the probability of the third conductive pattern 300 being oxidized. In some embodiments, the conductive oxide pattern and the third conductive pattern 300 include the same vertical projection shape.

After forming the conductive oxide pattern or the third conductive pattern 300, the first gate test line 271, the second gate test line 272, the first color test line 273, the second color test line 274, the third color test line 275 and the peripheral common signal test line 276 are adopted for circuit testing. In some embodiments, in addition to performing circuit testing after forming the conductive oxide pattern, an AOI is performed to determine whether the conductive oxide pattern is defective.

At this point, the pixel array substrate 10A is almost completed. In some embodiments, after the pixel array substrate 10A is completed, the pixel array substrate 10A is cut along the cutting line CT. In some embodiments, the first test line 160, the second test line 260, the first common signal test line 134 and the second common signal test line 234 are cut, and the first gate test line 271, the second gate test line 272, the first color test line 273, the second color test line 274, the third color test line 275, the peripheral common signal test line 276, the transfer electrode 320 and the common signal transfer electrode 330 are removed. In some embodiments, a blade is used to cut the first test line 160, the second test line 260, the first common signal test line 134 and the second common signal test line 234 of the pixel array substrate 10A, and no additional laser cutting process is required to cut off the test line.

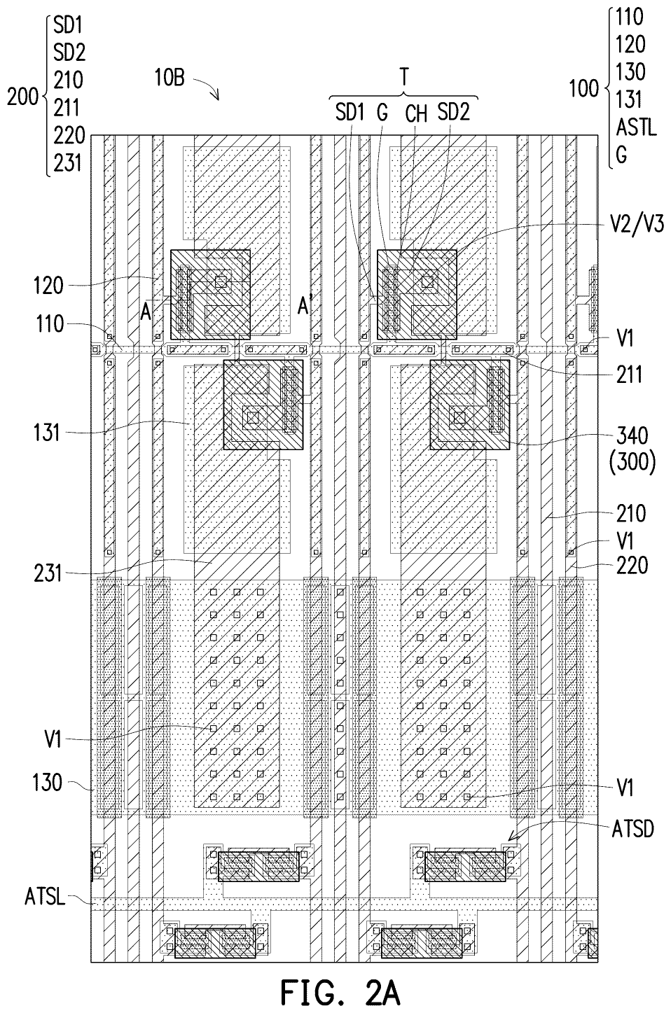

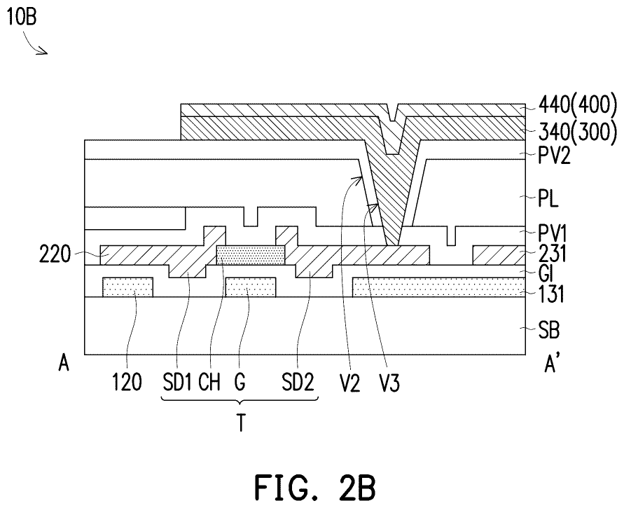

FIG. 2A is a partial top view of a pixel array substrate 10B according to an embodiment of the present disclosure. FIG. 2B is a schematic cross-sectional view taken along line A-A′ of FIG. 2A. It should be noted here that the embodiments of FIG. 2A and FIG. 2B adopt the reference numbers and part of the content of the embodiments of FIG. 1A to FIG. 1C, where the same or similar numbers are used to represent the same or similar elements, and descriptions of the same technical content are omitted. For descriptions of omitted parts, reference may be made to the foregoing embodiments and will not be described again here.

Please refer to FIG. 2A and FIG. 2B. In this embodiment, a plurality of thin film transistors T are included on the active area. Each thin film transistor T includes a gate G, a first source/drain SD1, a second source/drain SD2 and a semiconductor channel CH. The gate G is electrically connected to the scan line 110. The semiconductor channel CH overlaps the gate G, and is separated from the gate G by a first dielectric layer GI. The first source/drain SD1 and the second source/drain SD2 are formed on the first dielectric layer GI and are electrically connected to the semiconductor channel CH. The first source/drain SD1 is electrically connected to the data line 220.

In some embodiments, a capacitor electrode 131, a data line reinforcement structure 120 and a scan line reinforcement structure 211 are further disposed on the active area. The capacitor electrode 131 overlaps the common electrode line 231. The data line reinforcement structure 120 overlaps the data line 220, wherein the data line 220 is electrically connected to the data line reinforcement structure 120 through the opening V1 in the first dielectric layer GI. The scan line reinforcement structure 211 overlaps the scan line 110, wherein the scan line reinforcement structure 211 is electrically connected to the scan line 110 through the opening V1 in the first dielectric layer GI.

The first common electrode connection line 130 is electrically connected to the common electrode line 231 through the opening V1 in the first dielectric layer GI.

In some embodiments, the gate G, the scan line 110, the data line reinforcement structure 120, the first common electrode connection line 130 and the capacitor electrode 131 all belong to the first conductive pattern 100, and the first source/drain electrode SD1, the second source/drain SD2, the gate signal line 210, the scan line reinforcement structure 211, the data line 220 and the common electrode line 231 all belong to the second conductive pattern 200.

The second dielectric layer PV1 is formed on the second conductive pattern 200. The planarization layer PL is formed on the second dielectric layer PV1 and has an opening V2 overlapping the second source/drain SD2. The third dielectric layer PV2 is formed on the planarization layer PL and has a plurality of openings V3, wherein at least a portion of the openings V3 are located in the opening V2 of the planarization layer PL and extend through the second dielectric layer PV1.

The third conductive pattern 300 is formed on the third dielectric layer PV2 and includes the pixel electrode 340. The pixel electrode 340 is electrically connected to the second source/drain SD2 through the opening V3.

The conductive oxide pattern 400 is formed on the third conductive pattern 300 and includes a protective structure 440 on the pixel electrode 340.

In some embodiments, the antistatic structure ATSL and the antistatic diode ATSD are optionally included in the peripheral area. The antistatic diode ATSD is electrically connected to the antistatic structure ATSL and the data line 220.

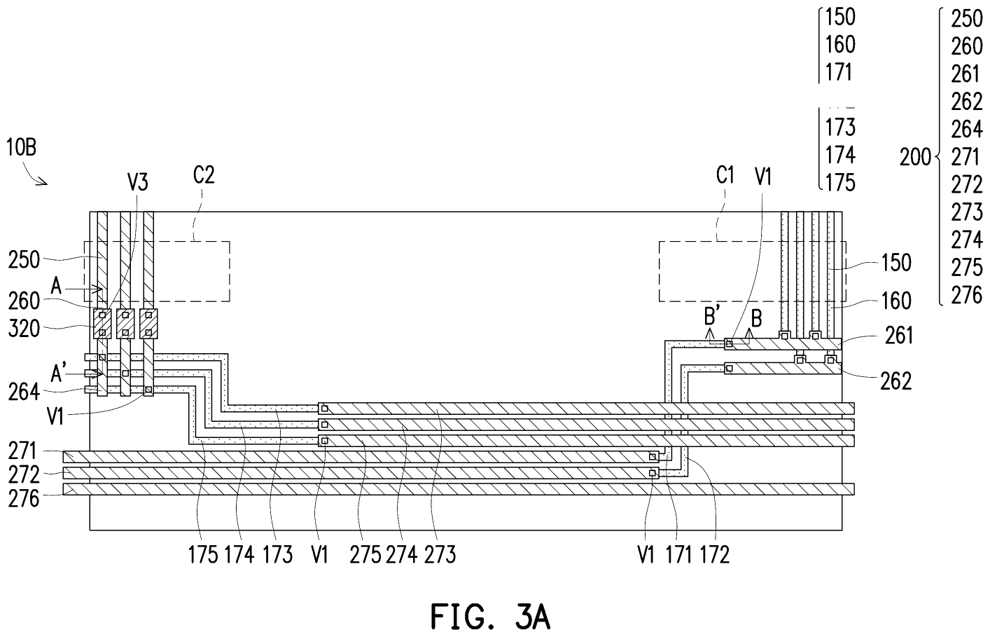

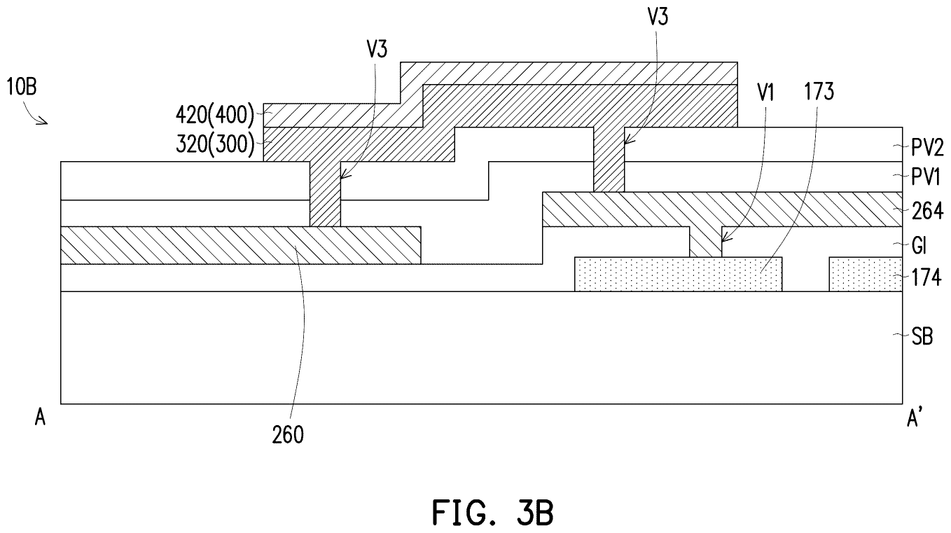

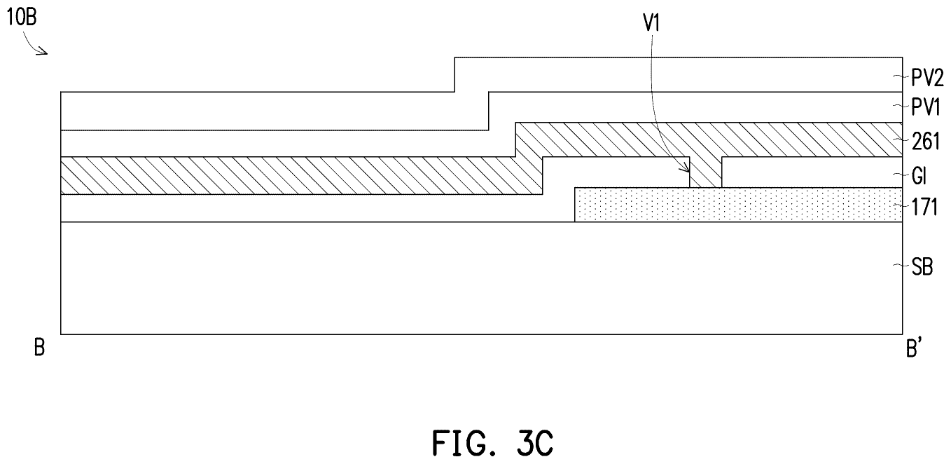

FIG. 3A is a partial top view of a pixel array substrate 10B according to an embodiment of the present disclosure. FIG. 3B is a schematic cross-sectional view taken along line A-A′ of FIG. 3A. FIG. 3C is a schematic cross-sectional view taken along line B-B′ of FIG. 3A. FIG. 2A to FIG. 3C illustrate the pixel array substrate 10B. FIG. 2A and FIG. 2B show the boundary between the active area and the peripheral area, and FIG. 3A to FIG. 3C show the location of the peripheral area.

Referring to FIG. 3A to FIG. 3C, the first conductive pattern 100 of the pixel array substrate 10B further includes a first gate test line extension portion 171, a second gate test line extension portion 172, a first color test line extension portion 173, a second color test line extension portion 174 and a third color test line extension portion 175. The first gate test line 271, the second gate test line 272, the first color test line 273, the second color test line 274 and the third color test line 275 are electrically connected to the first gate test line extension portion 171, the second gate test line extension portion 172, the first color test line extension portion 173, the second color test line extension portion 174 and the third color test line extension portion 175 through the corresponding opening V1.

The second conductive pattern 200 of the pixel array substrate 10B further includes a first transfer structure 261, a second transfer structure 262 and a second transfer structure 264. The first transfer structure 261 electrically connects the first portion of the first test lines 160 to the first gate test line extension portion 171 through the corresponding opening V1, and the second transfer structure 262 electrically connects the second portion of the first test lines 160 to the second gate test line extension portion 172 through the corresponding opening V1.

The first portion of the second transfer structures 264 is electrically connected to the first portion of the second test lines 260 through the first portion of the transfer electrodes 320, and is further electrically connected to the first portion of the data lines 220. The second portion of the second transfer structures 264 is electrically connected to the second portion of the second test lines 260 through the second portion of the transfer electrodes 320, and is further electrically connected to the second portion of the data lines 220. The third portion of the second transfer structures 264 is electrically connected to the third portion of the second test lines 260 through the third portion of the transfer electrodes 320, and is further electrically connected to the third portion of the data lines 220. The first portion of the second transfer structures 264, the second portion of the second transfer structures 264 and the third portion of the second transfer structures 264 are electrically connected to the first color test line 273, the second color test line 274 and the third color test line 275 through the corresponding opening V1 respectively. Through such an arrangement, it is possible to allow the first color test line 273 to be electrically connected to the first portion of the data lines 220, allow the second color test line 274 to be electrically connected to the second portion of the data lines 220, and allow the third color test line 275 to be electrically connected to the third portion of the data lines 220.

In this embodiment, the conductive oxide pattern 400 of the pixel array substrate 10B further includes a protective structure 420. The protective structure 420 covers the transfer electrode 320.

FIG. 4A to FIG. 4E are schematic top views of a fabrication method of a display device 1 according to an embodiment of the present disclosure. First, a pixel array substrate 10 is provided. Descriptions of the structure and fabrication method of the pixel array substrate 10 may be derived from the pixel array substrate 10A of FIG. 1A to FIG. 1C or the pixel array substrate 10B of FIG. 2A to FIG. 3C, and related details will not be described again.

The pixel array substrate 10 is cut along the cutting line CT to remove the first gate test line, the second gate test line, the first color test line, the second color test line, the third color test line and the peripheral common signal test lines (please refer to FIG. 1C or FIG. 3A). In some embodiments, the pixel array substrate 10 is cut to obtain the pixel array substrate 10′, and then a cleaning process is performed to remove residues from the pixel array substrate 10′.

Referring to FIG. 4B, a conductive structure 11 is formed on the pixel array substrate 10′. In some embodiments, the conductive structure 11 includes a conductive adhesive or other conductive materials, such as a silver adhesive. In some embodiments, the conductive structure 11 is electrically connected to the second common signal test line 234 (please refer to FIG. 1C).

Referring to FIG. 4C, the display medium film 20 is attached to the pixel array substrate 10′. For example, a roller is utilized to press the display medium film 20 onto the pixel array substrate 10′. In some embodiments, before the display medium film 20 is attached to the pixel array substrate 10′, infrared rays or other methods are utilized to preheat the pixel array substrate 10′, so that the display medium film 20 may be better attached to the pixel array substrate 10′.

In some embodiments, the display medium film 20 includes a display medium, a transparent common electrode and a resin substrate, wherein the transparent common electrode is electrically connected to the conductive structure 11, and is electrically connected to the pixel array substrate 10′ through the conductive structure 11. In this step, a display medium, a transparent common electrode and a resin substrate are provided on the substrate of the pixel array substrate 10′.

In some embodiments, after the display medium film 20 is attached to the pixel array substrate 10′, the protective film and/or the barrier film is attached to the display medium film 20.

Referring to FIG. 4D, the first chip on film package structure COF1 and the second chip on film package structure COF2 are bonded to the pixel array substrate 10′. For example, the first chip on film package structure COF1 and the second chip on film package structure COF2 are respectively disposed on the first bonding area C1 (please refer to FIG. 1C) and the second bonding area C2 (please refer to FIG. 1C). The first chip on film package structure COF1 is electrically connected to the gate signal pad 150 (please refer to FIG. 1C), and the second chip on film package structure COF2 is electrically connected to the data line signal pad 250. In some embodiments, the second chip on film package structure COF2 is also electrically connected to the first common electrode pad 133 and the second common electrode pad 233. Next, a functional test is performed on the pixel array substrate 10′ and the display medium film 20.

In some embodiments, in addition to bonding the first chip on film package structure COF1 and the second chip on film package structure COF2 to the pixel array substrate 10′, other chips will also be bonded onto the pixel array substrate 10′. In some embodiments, since there is no need to use a laser cutting process to disconnect the test circuits on the periphery of the pixel array substrate, there will be no splash debris generated by the laser cutting process on the pixel array substrate 10′, and therefore the risk of short circuit between the first chip on film package structure COF1 and the second chip on film package structure COF2 is reduced. Additionally, since the test circuit is disposed between the first bonding area C1 (please refer to FIG. 1C) and the edge of the substrate SB (please refer to FIG. 1C) and between the second bonding area C2 (please refer to FIG. 1C) and the edge of the substrate SB (please refer to FIG. 1C), and the test circuit has been removed after the cutting process. Therefore, a flatter terrain may be provided around the first bonding area C1 and the second bonding area C2, thus preventing the adhesive overflow problem caused by the first chip on film package structure COF1 and the second chip on film package structure COF2 during the bonding process.

Referring to FIG. 4E, a sealing ring 30 is formed around the display medium film 20 to improve the stability between the pixel array substrate 10′ and the display medium film 20. The sealing ring 30 includes, for example, a photo-curable polymer material. For example, a photo-curable polymer material is applied around the display medium film 20, and then the photo-curable polymer material is cured by ultraviolet light.

Finally, the driver motherboard (or system board) is electrically connected to the pixel array substrate 10′. For example, the driver motherboard (or system board) is electrically connected to the pixel array substrate 10′ through the first chip on film package structure COF1 and/or the second chip on film package structure COF2.

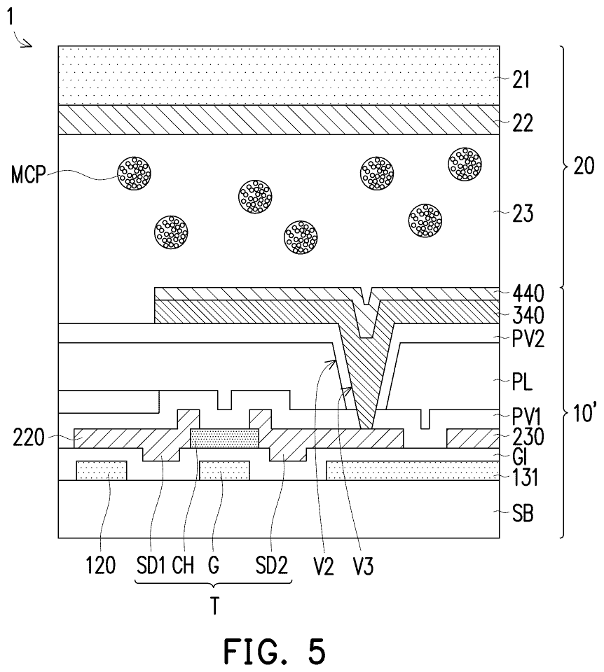

FIG. 5 is a schematic cross-sectional view of a display device 1 according to an embodiment of the present disclosure. It should be noted here that the embodiment of FIG. 5 adopts the reference numbers and part of the content of the embodiments of FIG. 2A to FIG. 2B and FIG. 4A to FIG. 4E, wherein the same or similar numbers are used to represent the same or similar elements, and descriptions of the same technical content are omitted. For descriptions of omitted parts, reference may be made to the foregoing embodiments and will not be described again here.

Please refer to FIG. 5. In this embodiment, the display medium film 20 includes a display medium 23, a transparent common electrode 22 and a resin substrate 21. The display medium 23 includes, for example, microcapsules MCP. Microcapsules MCP contain microparticles with different colors and transparent liquid, and the microparticles are charged/subcharged. In the embodiment, the arrangement of particles in the microcapsules MCP may be controlled by the electric field between the transparent common electrode 22 and the pixel electrode 340, thereby generating different images.

FIG. 6 is a three-dimensional schematic view of an open/short test according to an embodiment of the present disclosure. Referring to FIG. 6, the conductive pattern CP is scanned through the discharge sensor S1 and the power receiving sensor S2. The conductive pattern CP includes a plurality of conductive features arranged in the scan direction SND.

By providing an alternating current signal, the discharge sensor S1 is separated from the conductive features in the conductive pattern CP by a distance, and the power receiving sensor S2 is also separated from the conductive features in the conductive pattern CP by a distance. A capacitor using air as a medium is formed with such arrangement. Through this capacitor, the current signal may be discharged and received. While causing the discharge sensor S1 and the power receiving sensor S2 to discharge/receive power, the discharge sensor S1 and the power receiving sensor S2 are moved along the scan direction SND to scan the conductive pattern CP, thereby obtaining a series of test signals DA at peaks and valleys. When an abnormal wave pattern appears in the test signal DA, it may be determined that the conductive pattern CP has an open missing line or a short missing line at the corresponding position.

In summary, during the process of fabricating the pixel array substrate of the display device, through performing the open/short test, it is possible to instantly determine whether the conductive pattern has defects, and after the defects are determined, the defects in the conductive pattern may be repaired directly. Therefore, the yield of the conductive pattern may be improved.

What is claimed is:

1. A fabrication method of a display device, comprising:
forming a first conductive pattern on a substrate, wherein the first conductive pattern comprises a plurality of scan lines and a plurality of first test lines, wherein the plurality of scan lines extend along a first direction;
performing a first open/short test on the first conductive pattern;
forming a first dielectric layer on the substrate and the first conductive pattern;
forming a second conductive pattern on the first dielectric layer, wherein the second conductive pattern comprises a plurality of gate signal lines, a plurality of data lines, a plurality of second test lines, a first gate test line and a second gate test line, wherein the plurality of data lines and the plurality of gate signal lines extend along a second direction that is not parallel to the first direction, wherein the plurality of data lines are electrically connected to the plurality of second test lines respectively, the plurality of scan lines are electrically connected to the plurality of gate signal lines respectively, and the plurality of gate signal lines are electrically connected to the plurality of first test lines respectively, wherein a first portion of the plurality of gate signal lines are electrically connected to the first gate test line, the second portion of the plurality of gate signal lines are electrically connected to the second gate test line, and the first portion of the plurality of gate signal lines and the second portion of the plurality of gate signal lines are arranged alternately;
performing a second open/short test on the second conductive pattern; and
providing a display medium on the substrate.

2. The fabrication method of the display device according to claim 1, wherein the second conductive pattern further comprises a plurality of common electrode lines extending along the second direction, wherein the two adjacent common electrode lines comprise corresponding two of the plurality of data lines and a corresponding one of the plurality of gate signal lines sandwiched between the corresponding two of the plurality of data lines.

3. The fabrication method of the display device according to claim 2, wherein the first conductive pattern further comprises:
a first common electrode connection line electrically connected to the plurality of common electrode lines.

4. The fabrication method of the display device according claim 1, further comprising:
cutting the plurality of first test lines and the plurality of second test lines, and removing the first gate test line and the second gate test line.

5. The fabrication method of the display device according to claim 1, wherein the first open/short test and the second open/short test are non-contact detections that are performed using capacitors.

6. The fabrication method of the display device according to claim 1, wherein the second conductive pattern further comprises a first color test line, a second color test line and a third color test line, and the fabrication method of the display device further comprises:
forming a second dielectric layer on the second conductive pattern;
forming a third conductive pattern above the second dielectric layer so that the first color test line is electrically connected to a first portion of the plurality data lines, the second color test line is electrically connected to a second portion of the plurality of data lines, and the third color test line is electrically connected to a third portion of the plurality of data lines; and
performing a circuit testing by using the first color test line, the second color test line, the third color test line, the first gate test line and the second gate test line.

7. A pixel array substrate, comprising:
a substrate;
a first conductive pattern disposed on the substrate, wherein the first conductive pattern comprises a plurality of scan lines and a plurality of first test lines, wherein the plurality of scan lines extend along a first direction;
a first dielectric layer disposed on the substrate and the first conductive pattern;
a second conductive pattern disposed on the first dielectric layer, wherein the second conductive pattern comprises a plurality of gate signal lines, a plurality of data lines, a plurality of second test lines, a first gate test line and a second gate test line, wherein the plurality of data lines and the plurality of gate signal lines extend along a second direction that is not parallel to the first direction, wherein the plurality of data lines are electrically connected to the plurality of second test lines respectively, the plurality of scan lines are electrically connected to the plurality of gate signal lines respectively, and the plurality of gate signal lines are electrically connected to the plurality of first test lines respectively, wherein a first portion of the plurality of gate signal lines are electrically connected to the first gate test line, a second portion of the plurality of gate signal lines are electrically connected to the second gate test line, and first portion of the plurality of gate signal lines and the second portion of the plurality of gate signal lines are arranged alternately.

8. The pixel array substrate according to claim 7, wherein the second conductive pattern further comprises a plurality of common electrode lines extending along the second direction, wherein the two adjacent common electrode lines comprise corresponding two of the plurality of data lines and a corresponding one of the plurality of gate signal lines sandwiched between the corresponding two of the plurality of data lines.

9. The pixel array substrate according to claim 8, wherein the first conductive pattern further comprises:
a first common electrode ring electrically connected to the plurality of common electrode lines.

10. The pixel array substrate according to claim 7, wherein the second conductive pattern further comprises a first color test line, a second color test line and a third color test line, and the pixel array substrate further comprises:
a second dielectric layer disposed on the second conductive pattern; and
a third conductive pattern disposed above the second dielectric layer, wherein the first color test line is electrically connected to a first portion of the plurality data lines, the second color test line is electrically connected to a second portion of the plurality of data lines, and the third color test line is electrically connected to a third portion of the plurality of data lines.
